(19) United States
(12) Patent Application Publication
(10) Pub. No.: US 2009/0096052 A1
(43) Pub. Date: Apr. 16, 2009

(54) SEMICONDUCTOR DEVICE FOR RADIATION DETECTION

(75) Inventors: Anco Heringa, Eindhoven (NL); Johannes Albert Luijendijk, Eindhoven (NL); Joost Willem Christiaan Veltkamp, Nijmegen (NL); Wibo Daniel Van Noort, Wappingers Falls, NY (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/282,907

(22) PCT Filed: Mar. 9, 2007
(86) PCT No.: PCT/IB2007/050792

§ 371 Date: Sep. 15, 2008

(30) Foreign Application Priority Data
Mar. 15, 2006 (EP) 06111166.2
Mar. 23, 2006 (EP) 06111616.6

(51) Int. Cl. H01L 31/0232

(52) U.S. Cl. 257/435; 257/E31.127

(57) ABSTRACT

The invention provides a semiconductor device (11) for radiation detection in a semiconductor substrate (1) comprising a detection region (3), which detects charge carriers that are generated upon incidence of radiation (X, L) on the semiconductor device (11). The semiconductor device further (11) comprises a further detection region (13), which detects charge carriers that are generated upon incidence of radiation (X) on the semiconductor device (11). A shield (8, 18) extends over the further detection region (13), which prevents electromagnetic radiation (L) from entering the detection region (13). This way the invention provides a semiconductor device (11) for radiation detection in which the separation between the detection of electromagnetic radiation (L) and the detection of other radiation is improved. The invention further provides a detector (10) comprising the semiconductor device (11), and a processor (P) coupled to the detection region (3) and the further detection region (13) for generating an output signal (22) representing the electromagnetic radiation (L).

The invention relates to a semiconductor device for radiation detection.

Semiconductor based devices, or sensors, for detecting electromagnetic radiation are known in the art. These sensors are implemented in a semiconductor substrate in an IC (Integrated Circuit) technology such as an MOS (Metal Oxide Semiconductor), CMOS (Complementary Metal Oxide Semiconductor) or CCD (Charged Coupled Device) technology, utilizing, for example, so-called collection junctions, which are regions adapted for collecting charge carriers generated in the substrate by the electromagnetic radiation and which are either pn- or np-junctions.

Semiconductor based detectors for detecting ionizing radiation, such as X-rays, generally are based on indirect conversion detector techniques. In an indirect conversion detector a, for example, scintillation device is applied in which electromagnetic radiation is generated by the ionizing (X-ray) radiation hitting the scintillation device. This electromagnetic radiation enters the semiconductor substrate where it generates charge carriers that are subsequently detected by, for example, the collection junctions. However, a part of the ionizing radiation will also pass through the scintillation device and penetrate deeper into the semiconductor substrate than the electromagnetic radiation generated by the ionizing radiation striking on the scintillation device. Consequently, the ionizing radiation also generates unwanted or parasitic charge carriers in the semiconductor substrate, which influence and degrade the detection functionality of the electromagnetic radiation and hence the performance of the semiconductor based detector significantly.

U.S. Pat. No. 5,929,499 discloses a photodiode array, for use in an X-ray detector, which converts the energy of incident X-rays into a corresponding electrical signal. A scintillation device is applied, which converts incident X-rays into photons. The photodiode array, disposed following the scintillation device in the radiation propagation, absorbs the photons and a photocurrent is thus obtained that is proportional to the luminous intensity of the incident X-rays. The photodiode array is disposed on a substrate with an extraction diode connected between each two neighboring photodiodes. The anodes of all of the extraction diodes are connected together at a common anode contact, and a voltage is applied across the extraction diodes by connecting a voltage source to the common anode contact so that the extraction diodes are reversed biased and thus block current flow. In this way the photodiodes are electrically separated and X-rays, which may penetrate to a slight extent directly into the photodiode array, do not generate a noise signal and cross-talk between detector channels is substantially reduced.

It is therefore an object of the invention to provide a semiconductor device for radiation detection in which the separation between the detection of electromagnetic radiation and the detection of other than electromagnetic radiation is improved. The invention is defined by the independent claims. Advantageous embodiments are defined by the dependent claims.

The invention is, inter alia, based on the recognition that it is a disadvantage of the prior art device of U.S. Pat. No. 5,929,499 that it only obstructs X-ray induced parasitic current flow between the detection channels, or photodiodes, and it does not obstruct a further parasitic current flow between the substrate and the device. This further parasitic current flow is induced by the X-rays that penetrate directly into the photodiode array and also into the substrate below the photodiode, thereby creating charge carriers that are subsequently detected by the photodiodes. This disadvantageously influences the detection of the photons, because both the photons and the penetrating X-rays are detected by the photodiodes and contribute to the electrical signal.

The semiconductor device for radiation detection in a semiconductor substrate according to the invention comprises a detection region for detecting charge carriers that are generated upon incidence of radiation on the semiconductor device. The semiconductor device further comprises a further detection region for detecting charge carriers that are generated upon incidence of radiation on the semiconductor device, and over which a shield extends for preventing electromagnetic radiation from entering the detection region. The further detection region is blocked from electromagnetic radiation, but will detect remaining radiation, such as ionizing radiation, that penetrates through the shield and enters the further detection region. A part of the detection region, over which the shield does not extend, detects both the remaining radiation and the electromagnetic radiation. This enables a separation of the detection of the remaining radiation from the detection of electromagnetic radiation. For example, by comparing a first detection signal, generated by the further detection region, with a second detection signal, generated by the part of the detection region over which the shield does not extend, the contribution of the remaining radiation to the detection signals is separated from the contribution of the electromagnetic radiation to the detection signals. In a preferable embodiment the radiation comprises X-rays and visible light.

WO 2004/054005 describes an X-ray detector, comprising pixels with thin film transistors (TFT) and photo diodes on an insulating substrate, for converting X-rays into an electrical signal. The electrical signal may include leakage current flowing in the photo diodes or on a surface of the photo diodes. The X-ray detector therefore further includes dummy pixels including a light blocking member for blocking light incident on photo diodes which enables the determination of the leakage current flowing in the photo diodes in the absence of light. The differences with the invention are that the X-ray detector is on an insulating substrate, whereas the semiconductor device according to the invention is in a semiconductor substrate, and the light blocking member of the X-rays detector is applied for determining the leakage current flowing in the photo diodes, such as dark current, whereas the semiconductor device according to the invention applies the light blocking member for separating the detection of the remaining radiation, such as X-rays, from the detection of electromagnetic radiation.

In an embodiment of the device according to the invention a scintillation device extends over the semiconductor device, which scintillation device converts incoming ionizing radiation into electromagnetic radiation. In this way a device is obtained that is able to detect ionizing radiation in which the separation of the detection of ionizing radiation from electromagnetic radiation is further improved.

In another embodiment of the device according to the invention a barrier region, which is adjacent to the further detection region, prevents charge carriers that are generated in the semiconductor device adjacent to the further detection region from entering the further detection region. This improves the separation of the further detection region from adjacent regions, for example the detection region, by preventing charge carriers generated in adjacent regions from entering into the further detection region, and vice versa, thereby advantageously improving the detection of the remaining radiation.

In an embodiment of the device according to the invention the semiconductor device further comprises a substrate barrier region, which is an obstacle between the semiconductor substrate and the detection region, and between the semiconductor substrate and the further detection region, for charge carriers that are generated in the semiconductor substrate by penetration of ionizing radiation into the semiconductor substrate. By placing an obstruction for charge carriers, induced by ionizing radiation in the substrate, between the substrate and the semiconductor device, the number of parasitic charge carriers that are generated by the ionizing radiation in the substrate and that reach the detection region and the further detection region, is reduced significantly. In a preferred embodiment, the substrate barrier region comprises an isolation material.

In an embodiment of the device according to the invention the shield comprises a conductive layer that extends over the further detection region. The conductive layer may be advantageously used both as shield and electrical connection layer between devices. In a preferred embodiment the shield further comprises a contact region of a further conductive material that, in projection, surrounds the further detection region and is connected to the conductive layer. The contact region prevents charge carriers generated in regions, adjacent to the contact region, from entering into a region extending over the further detection region, and vice versa, thereby advantageously improving the detection of the remaining radiation.

These and other aspects of the invention will be further elucidated and described with reference to the drawings, in which:

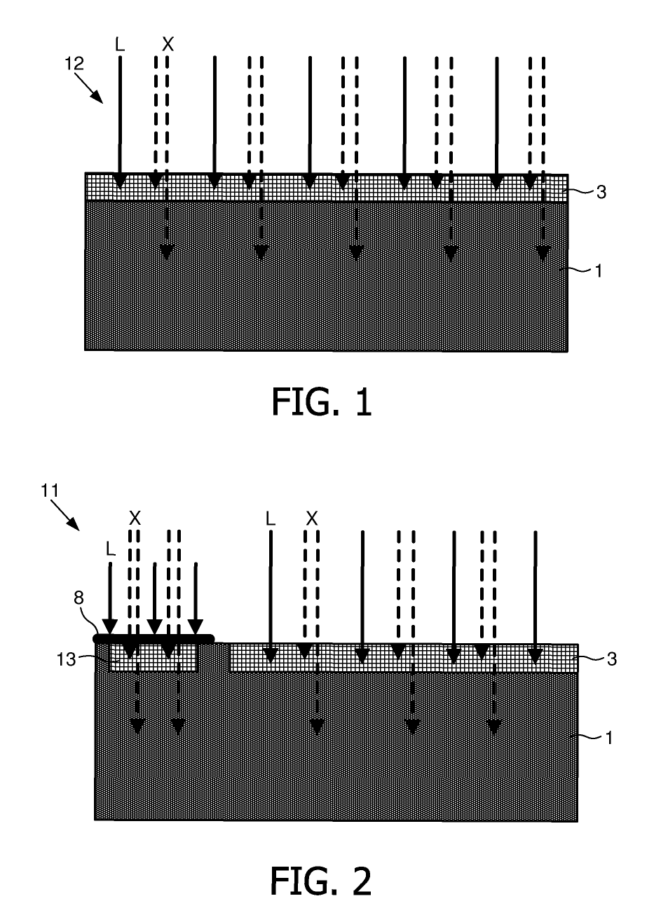

FIG. 1 is a diagrammatic cross-sectional view of an embodiment of a device according to the prior art;

FIGS. 2-4 are diagrammatic cross-sectional views of embodiments of a device according to the invention; and

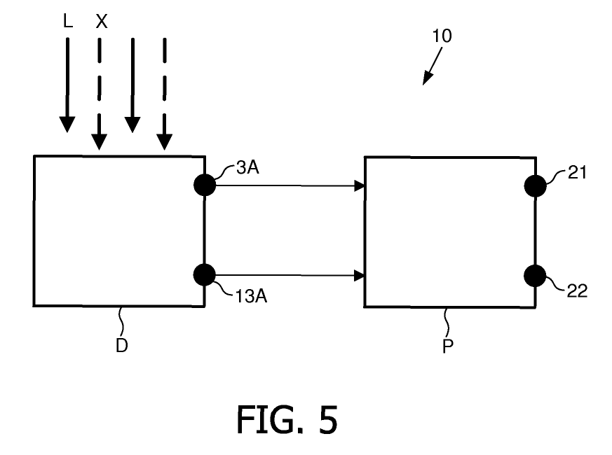

FIG. 5 is a schematic representation of an X-ray detector according to an embodiment of the invention.

The Figures are not drawn to scale. In general, identical components are denoted by the same reference numerals in the figures.

A scintillation device emits low-energy photons or electromagnetic radiation, usually in the visible range, when struck by a high-energy charged particle, such as X-rays X. The X-rays X pass through the scintillation device thereby generating electromagnetic radiation, which is subsequently detected by a semiconductor device 12. However, also the X-rays X that pass through the scintillation device will penetrate the semiconductor device 12. FIG. 1 illustrates that electromagnetic radiation L, indicated by arrows L, and originating from the scintillation device (not shown), which is struck by X-rays X, hits on and penetrates the semiconductor device 12. Furthermore, also the X-rays, indicated by dashed arrows X, passing through the scintillation device (not shown), enter the semiconductor device 12. The semiconductor device 12 comprises a detection region 3, which is able to detect the electromagnetic radiation L by detecting, in this case, electrons that are generated by the electromagnetic radiation L, using devices and techniques that are known in the art. Furthermore, the semiconductor device 12 comprises a substrate region 1, here of a p-type semiconductor material, into which the X-rays X will penetrate, whereas the electromagnetic radiation L, having a relatively lower energy than the X-rays X, will only penetrate into the detection region 3. The X-rays X generate electrons and holes in the substrate region 1, and part of the, in this case, X-ray generated electrons penetrate into the detection region 3 thereby disturbing the detection of the electrons that are generated by the electromagnetic radiation L which disadvantageously affects the performance of the semiconductor device 12 for detecting electromagnetic radiation L.

FIG. 2 shows a cross-sectional view of an embodiment of a semiconductor detection device 11 according to the invention comprising the p-type semiconductor substrate region 1 with the detection region 3. The detection region 3 is able to detect, in this case, electrons that are generated by the electromagnetic radiation L in the detection region 3 and generated by the X-rays X in the detection region 3 and the substrate region 1. Adjacent to the detection region 3, a further detection region 13 is provided over which a shield 8 extends. The shield 8 prevents the electromagnetic radiation L from entering the further detection region 13 and comprises, for example, metal, heavily doped polysilicon or an anti-reflective coating material. The further detection region 13 detects only the, in this case, electrons created by the X-rays X and generates a first signal 13A (see FIG. 5), which is, amongst others, a function of the X-rays X. The detection region 3 detects both the, in this case, electrons that are created by the X-rays X and the, in this case, electrons that are created by the electromagnetic radiation L and generates a second signal 3A (see FIG. 5), which is, amongst others, a function of both the X-rays X and the electromagnetic radiation L. The two detection regions 3,13 enable a discrimination between electrons generated by the X-rays X and electrons generated by the electromagnetic radiation L, because by comparing the first signal 13A and the second signal 3A, a separate X-ray signal 21 and a separate electromagnetic radiation signal 22 can be extracted, which significantly improves both the detection of the X-rays X and the electromagnetic radiation L. It should be noted that the scintillation device may be used, which results in an indirect conversion detection device, but it also possible to apply this embodiment without the scintillation device resulting in a direct conversion detection device.

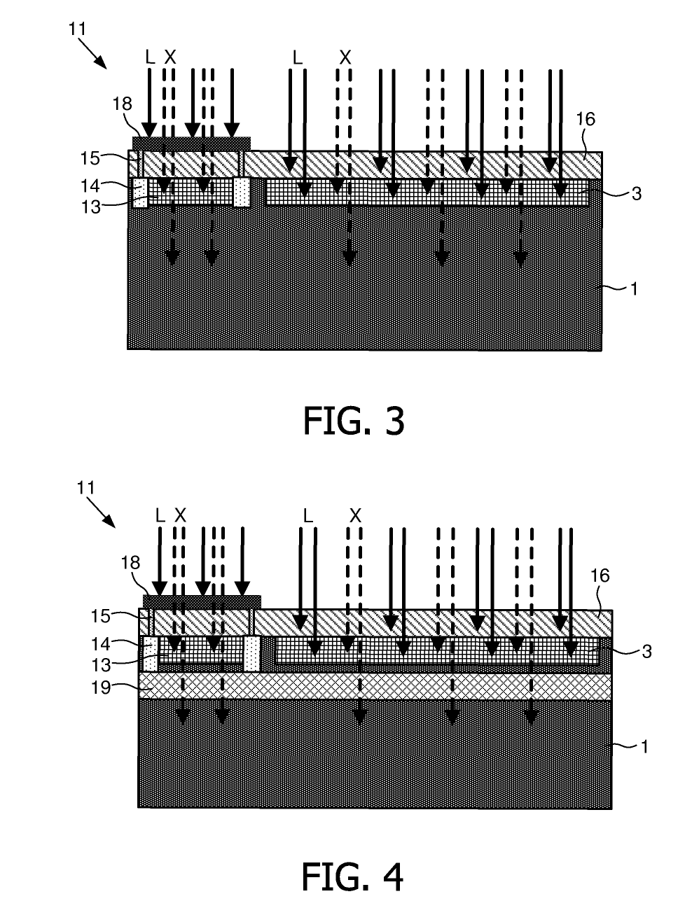

FIG. 3 shows a cross-sectional view of an embodiment of a semiconductor detection device 11 according to the invention comprising the p-type semiconductor substrate region 1 with the detection region 3 and, adjacent to the detection region 3, the further detection region 13. An insulating layer 16 extends over the detection region 3, the further detection region 13 and the substrate region 1. A shield layer 18 on the insulation layer 16 extends over the further detection region 13. The shield layer 18 prevents the electromagnetic radiation L from entering the further detection region 13 and comprises, in this case, a conductive material like aluminum or tungsten. It should be noted that also another material may be used, which is able to prevent the electromagnetic radiation L from entering the further detection region 13. The shield layer 18 is, via a contact region 15, in this case electrically connected to a barrier region 14 that surrounds the further detection region 13. The contact region 15 also surrounds, in projection, the further detection region 13 and comprises, for example, aluminum or tungsten. The barrier region 14 comprises, for example, n-type semiconductor material, thereby sinking or draining the X-ray generated electrons that reach the barrier region 14 via diffusion. In another embodiment, as is shown in FIG. 4, the substrate region 1 comprises a substrate barrier region 19 which prevents charge carriers that are generated in the substrate region 1 from entering the detection region 3 and the further detection region 13. The substrate region 19 is, for example, of an electrically isolating material, such as silicon dioxide, which, in this case, advantageously forms part of a so-called SOI (Silicon On Insulator) substrate.

FIG. 5 shows schematically an arrangement of a detector 10 according to the invention in which the discrimination between the separate X-ray signal 21 and the separate electromagnetic radiation signal 22 is achieved. A detecting device D, which comprises a multiple of the semiconductor devices 11 according to the invention, generates the first signal 13A, which is a function of the X-rays X as detected by the further detection region 13, and the second signal 3A, which is a function of both the X-rays X and the electromagnetic radiation L as detected by the detection region 3. The first signal 13A and the second signal 3A are input for a processor P, which subsequently computes the separate X-ray signal 21 and the separate electromagnetic radiation signal 22.

In summary, the invention provides a semiconductor device for radiation detection in a semiconductor substrate comprising a detection region, which detects charge carriers that are generated upon incidence of radiation on the semiconductor device. The semiconductor device further comprises a further detection region, which detects charge carriers that are generated upon incidence of radiation on the semiconductor device. A shield extends over the further detection region, which prevents electromagnetic radiation from entering the detection region. This way the invention provides a semiconductor device for radiation detection in which the separation between the detection of electromagnetic radiation and the detection of other radiation is improved. The invention further provides a detector comprising the semiconductor device, and a processor coupled to the detection region and the further detection region for generating an output signal representing the electromagnetic radiation.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. A semiconductor device (11) for radiation detection in a semiconductor substrate (1) comprising:
a detection region (3) for detecting charge carriers that are generated upon incidence of radiation (X,L) on the semiconductor device (11),
a further detection region (13) for detecting charge carriers that are generated upon incidence of radiation (X) on the semiconductor device (11), and
a shield (8,18) extending over the further detection region (13) for preventing electromagnetic radiation (L) from entering the detection region (13).

2. A device as claimed in claim 1, in which the radiation comprises X-rays (X) and visible light (L).

3. A device as claimed in claim 1, further comprising a scintillation device, extending over the semiconductor device (11), for converting incoming ionizing radiation (X) into electromagnetic radiation (L).

4. A device as claimed in claim 1, further comprising a barrier region (14), which is adjacent to the further detection region (13), for preventing charge carriers that are generated in the semiconductor device adjacent to the further detection region (13) from entering the further detection region (13).

5. A device as claimed in claim 1, further comprising a substrate barrier region (19), which is an obstacle between the semiconductor substrate (1) and the detection region (3), and between the semiconductor substrate (1) and the further detection region (13), for charge carriers that are generated in the semiconductor substrate (1) by penetration of ionizing radiation (X) into the semiconductor substrate (1).

6. A device as claimed in claim 5, in which the substrate barrier region (19) comprises an electrically isolating material.

7. A device as claimed in claim 1, in which the shield (8,18) comprises a conductive layer (18) that extends over the further detection region (13).

8. A device as claimed in claim 7, in which the shield (8,18) further comprises a contact region (15) of a further conductive material that, in projection, surrounds the further detection region (13) and is connected to the conductive layer (18).

9. A detector (10) comprising the semiconductor device (11) as claimed in claim 1, and a processor (P) coupled to said detection region (3) and said further detection region (13) for generating an output signal (22) representing said electromagnetic radiation (L).
